(19) United States
(12) Patent Application Publication
(10) Pub. No.: US 2018/0191339 A1
(43) Pub. Date: Jul. 5, 2018

(54) Gate Driver Controlling a Collector to Emitter Voltage Variation of an electronic Switch and Circuits Including the Gate Driver

(71) Applicant: TM4 INC., Boucherville (CA)

(72) Inventor: Jean-Marc CYR, Québec (CA)

(21) Appl. No.: 15/127,380

(22) PCT Filed: Mar. 18, 2015
(86) PCT No.: PCT/CA2015/050202

§ 371 Date: Sep. 19, 2016

Related U.S. Application Data
(60) Provisional application No. 61/955,875, filed on Mar. 20, 2014.

(51) Int. Cl. H03K 17/081; H02M 1/08; H03K 17/16

(52) U.S. Cl. CPC H03K 17/08104; H02M 1/08; H02M 2001/0058; H03K 17/168; H03K 17/08116; H03K 17/163

(57) ABSTRACT

The present disclosure introduces a gate driver used to drive a power electronic switch of a commutation cell. The gate driver comprises a turn-off current source connected to a gate of the power electronic switch and an additional current source. The additional current source is in parallel to the turn-off current source of the gate driver and is configured to control a collector to emitter voltage variation at turn off of the power electronic switch. A circuit combining the gate driver with a commutation cell having a power electronic switch, a circuit combining a pair of gate drivers with a leg having two commutation cells including two power electronic switches and a converter including such circuits are also disclosed.

### TECHNICAL FIELD

The present disclosure relates to the field of power electronics. More specifically, the present disclosure relates to a gate driver for controlling a collector to emitter voltage variation of an electronic switch and to circuits including the gate driver.

### BACKGROUND

Commutation cells are commonly used in electronic systems that require conversion of a voltage source, including both DC-DC and DC-AC converters. FIG. 1 is an idealized circuit diagram of a conventional commutation cell having a single power electronic switch and a single freewheel diode with a voltage source and a current load. A commutation cell 10 converts a DC voltage V_{bus} from a voltage source 12 (or from a capacitor 20) into a current source Iₒᵤₜ 11 (or into an inductance) that usually generates a voltage Vₒᵤₜ appropriate for a load 14, which may be a resistive load, an electric motor, and the like. The commutation cell 10 comprises a freewheel diode 16, a controlled power electronic switch 18, for example an isolated gate bipolar transistor (IGBT) as shown on FIG. 1. Another commutation cell may replace the IGBT with a metal-oxide-semiconductor field-effect transistor (MOSFET), with a bipolar transistor, and the like. The communication cell 10 also comprises the capacitor 20 and an inductance 28. The capacitor 20 limits variations of the voltage V_{bus} of the voltage source 12 while the inductance 28 limits the variations of the output current Iₒᵤₜ 11. A gate driver (not shown in FIG. 1 but shown on later Figures) controls turning on and off of the power electronic switch 18. FIG. 1 illustrates a configuration of the commutation cell 10, of the load 14, and of the voltage source 12, in which energy flows from the voltage source 12 to the load 14, i.e. from left to right on the drawing. The commutation cell 10 can also be used in a reverse configuration in which energy flows in the opposite direction.

When turned on, the power electronic switch 18 allows current to pass therethrough, from its collector 22 to its emitter 24. The power electronic switch 18 can be approximated as a closed circuit. When the power electronic switch 18 turns off, it becomes an open circuit and a collector to emitter voltage V_{ce} is built thereacross.

The gate driver applies a variable control voltage between the gate 26 and the emitter 24 of the power electronic switch 18. For some types of power electronic switches such as bipolar transistors, the gate driver may act as a current source instead of as a voltage source. Generally, when the voltage applied between the gate 26 and the emitter 24 is “high”, the power electronic switch 18 allows passing of current from the collector 22 to the emitter 24. When the voltage applied between the gate 26 and the emitter 24 is “low”, the power electronic switch 18 limits passage of current therethrough while the voltage V_{ce} increases. In more details, a voltage difference between the gate 26 and the emitter 24, denoted V_{ge}, is controlled by the gate driver. When V_{ge} is greater than a threshold V_{ge(th)} for the power electronic switch 18, the switch 18 is turned on and the voltage V_{ce} between the collector 22 and the emitter 24 becomes near zero. When V_{ge} is lower than V_{ge(th)}, the power electronic switch 18 is turned off and a current from the collector 22 to the emitter 24 becomes near zero while, at the same time, V_{ce} tends to reach V_{bus}.

When the power electronic switch 18 is turned on, the current Iₒᵤₜ 11 flows from the voltage source 12 (and transiently from the capacitor 20) through the load 14 and through the collector 22 and the emitter 24. When the power electronic switch 18 is turned off, the current Iₒᵤₜ 11 circulates from the load 14 and passes in the freewheel diode 16. Turning on and off of the power electronic switch 18 at a high frequency allows the current Iₒᵤₜ 11, in the output inductance 28, to remain fairly constant.

It should be observed that, in the case of other power electronic switch types, for example bipolar transistors, the term “gate” may be replaced with “base”, the base being controlled by a current as opposed to the gate that is controlled by a voltage. These distinctions do not change the overall operation principles of the commutation cell 10.

FIG. 2 is another circuit diagram of the conventional commutation cell of FIG. 1, showing parasitic inductances and capacitances. In contrast with the idealized model of FIG. 1, connections between components of an actual commutation cell define parasitic (stray) inductances while isolation between components defines parasitic capacitances. Though the parasitic inductances are distributed at various places within the commutation cell 10, a suitable model presented in FIG. 2 shows two (2) distinct inductances representing the overall parasitic inductance, including an emitter inductance 30 of the power electronic switch 18 and an inductance 32 representative of all other parasitic inductances (other than the emitter inductance 30) around a high frequency loop 34 formed by the freewheel diode 16, the power electronic switch 18 and the capacitor 20. The high frequency loop 34 is a path where current changes significantly upon switching of the power electronic switch 34. It should be noted that an output inductance Lₒᵤₜ 28 is not part of the high frequency loop because its current remains fairly constant through the commutation period. Significant parasitic capacitances include a collector to gate capacitance 36 and a gate to emitter capacitance 38.

FIG. 3 is an illustration of an equivalent circuit of a typical IGBT. The IGBT 40 combines, in a single device, the simple and low power capacitive gate-source characteristics of metal-oxide-semiconductor field-effect transistors (MOSFET) with high-current and low-saturation-voltage capability of bipolar transistors. An IGBT 40 can be used as the power electronic switch 18 of FIGS. 1 and 2 and has the same gate, 26, collector 22 and emitter 24. In more details, the equivalent circuit of the IGBT 40 is made from one MOSFET 42 and two bipolar transistors 44, 46 connected in a thyristor configuration 48, the equivalent circuit of the thyristor being the same as the output stage of the IGBT 40: two bipolar transistors, including one PNP transistor 44 and one NPN transistor 46, that polarize each other. The input of the IGBT 40 is made from an equivalent MOSFET 42 that is voltage-controlled, has low-power gate driver dissipation and provides high speed switching. The output of the IGBT 40 is made with the two bipolar transistors 44, 46 connected in the thyristor configuration 48 to provide a powerful output.

While the bipolar transistors 44, 46 are capable of supporting high power levels, their reaction time does not match that of the MOSFET 42.

When the IGBT 40 is subjected to a sufficient gate to emitter voltage V_{ge}, the MOSFET 42 turns on first. This causes current to circulate through the base-emitter junction of the PNP transistor 44, turning the PNP transistor 44 on. This, in turn, turns on the NPN transistor 46, following which the IGBT 40 is ready to deliver high-level current through the collector 22 and the emitter 24.

The MOSFET 42 can take the whole current of the IGBT 40 under light loads, via a drift region 50, which implies that the IGBT 40 is capable of turning on quickly with a well-controlled variation (di/dt) of the current flowing through the collector 22 and the emitter 24. To carry the current at full rating of the IGBT 40 under heavier loads, the bipolar transistors 44, 46 need to turn on. Speed of the full turn on of the IGBT 40 depends on the temperature and on the amplitude of the current flowing through the collector 22 and the emitter 24.

The MOSFET 42 also switches off first at turn off of the IGBT 40. Even when the MOSFET 42 is completely off, the two bipolar transistors 44, 46 remain conductive for a brief moment, until minority carriers located on their base-emitter junctions are removed. The body region 52 of the IGBT 40 allows the thyristor 48 to turn off by turning the NPN transistor 46 off first. Once the NPN transistor 48 is off, the minority carriers of the base-emitter junction of the PNP transistor 44 are removed, effectively terminating the turn off process of the IGBT 40.

Because the output stage of the IGBT 40 formed by the bipolar transistors 44, 46 is slower than its input stage formed by the MOSFET 42, there is a limit above which speeding up a control signal applied at the gate 26 will have no significant impact on the switching time of the IGBT 40. For example, during turn on, at a greater current load than can be handled by the MOSFET 42, the full current load can only be supported once the thyristor 48 (i.e. the two bipolar transistors 44, 46) is turned on. In the same way, during turn off, even when accelerating a control signal applied at the gate 26, the thyristor 48 remains conductive until the minority carriers are removed.

The inherent non-linearity of the various components of the IGBT 40 complicates its control and makes it difficult to operate with maximal efficiency. While it is desired to rapidly switch the IGBT 40 on and off in order to reduce as much as possible losses during the commutation process, it is also desired to avoid excessive collector to emitter overvoltage of the IGBT 40 while also avoiding excessive recovery current of the freewheel diode 16.

FIG. 4 is a graph showing an example of switching losses of an IGBT as a function of gate resistance values. Energy losses, denoted Eₒₙ when related to turn-on of the IGBT 40 and E_{off} when related to turn-off of the IGBT 40, are expressed in millijoules (mJ) as a function of a value of a gate resistor (R_{G}) that represents an output impedance of the gate driver controlling the IGBT 40. Because the IGBT 40 behaves as a voltage controlled current source while in its linear region, the collector to emitter current flowing through the IGBT 40 increases with a voltage V_{ge} applied between the gate 26 and the emitter 24. It is well known that bipolar transistors are faster at turn on than at turn off. For this reason, losses at turn on of the IGBT 40 are mainly dependent on the resistance value R_{G} of the gate driver, which defines an equivalent on/off current source and provides the voltage V_{ge} between the gate 26 and the emitter 24. On the other hand, the MOSFET 42 may be turned off completely while the thyristor 48 is still conducting, until the charges on the base-emitter of the bipolar transistors 44, 46 are completely removed. As a result, a slope of the losses as a function of the gate resistor R_{G} is lower for the turn off than the same curve for the turn on. On FIG. 4, though losses are somewhat temperature-dependent, losses at turn on (60, 62) are impacted by recovery current in the freewheel diode 16 and therefore tend to be greater than losses at turn off (64, 66)

FIG. 5 is a circuit diagram of a conventional IGBT leg having a pair of power electronic switches and further showing a gate driver. Typically, three (3) legs as shown on FIG. 5 provide power to a three-phase AC motor. Alternatively, a pair of such legs can provide power to a single-phase AC motor. Some elements of the IGBT leg 70 are not shown on FIG. 5, in order to simplify the illustration. FIG. 5 includes elements introduced in the foregoing description of FIGS. 1 and 2. The IGBT leg 70 includes two (2) similar power electronic switches 18 and matching freewheel diodes 16. Pairs formed of the switches 18 and diodes 16 operate in tandem, the switch 18 at the top of the IGBT leg 70 (Q2) operating with the diode 16 at the bottom (D1), and vice-versa. FIG. 5 further shows a gate driver 72 connected to one (Q1) of the illustrated power electronic switches 18; another gate driver 72 connected to the other (Q2) power electronic switch 18 is not shown to simplify the illustration. In FIG. 5, the interconnection of two (2) switches 18 creates distinct parasitic inductances, including two (2) emitter inductances 30 and two (2) collector inductances 33.

The gate driver 72 has a positive supply voltage 74 and a negative supply voltage 76, an output 78 of the gate driver 72 being connected to the gate 26 of the power electronic switch 18. The positive supply voltage 74 of the gate driver 72 has a value denoted +V_{cc}, for example +15 volts above a ground reference (not shown) while the negative supply voltage 76 has value denoted −V_{d}d, for example −5 volts below the ground reference. An input (not shown) of the gate driver 72 is connected to a controller (also not shown) of the IGBT leg 70, as is well known in the art. A voltage at the output 78 of the gate driver 72 may go up to +V_{cc} and may go down to −V_{dd} in order to control and limit the voltage at the gate 26. The gate driver 72 may have an output resistance R_{G} (not shown). The input resistance of the power electronic switch 18 at the gate 26 may be very high, especially in the case of an IGBT 40 because its gate 26 actually consists of a MOSFET gate whose input resistance can be considered as infinite. However, presence of the parasitic capacitances 36 and 38 causes currents Iₒₙ and I_{off} to flow therethrough from the output 78 when the gate driver 72 alternates between +V_{cc} and −V_{dd}. Values and waveforms of the currents Iₒₙ and I_{off} are determined by the gate driver 72 voltages +V_{cc} and V_{dd}, and by the impedance formed by the output resistance R_{G}, if any, of the gate driver 72 and by the parasitic capacitances 36 and 38.

On FIG. 5, a current I_{igbt} flowing through the bottom power electronic switch 18 and through the bottom emitter parasitic inductance 30 is essentially equal to Iₒᵤₜ 11 when the bottom power electronic switch 18 is closed. At that time, Iₒᵤₜ 11 flows in the direction as shown on FIG. 5. The current I_{igbt} quickly reduces to zero (substantially) when the bottom power electronic switch 18 turns off.

When one of the power electronic switches 18 turns on or off, the current I_{igbt} flowing therethrough increases or diminishes at a fast rate. These variations of I_{igbt}, denoted di/dt, generate voltage across its emitter inductance 30, according to the well-known equation (1):

$${V}_{L} = L \cdot \frac{di}{dt} \qquad ( 1 )$$

wherein V_{L} is a voltage induced across an inductance and L is an inductance value.

For each of the power electronic switches 18, a voltage V_{Le} is generated across the emitter parasitic inductance 30. On FIG. 5, the polarities shown across the high frequency loop inductances, including the collector inductances 33 and the emitter inductances 30, reflect voltages obtained upon turn off of the power electronic switches 18, when the I_{igbt} current diminishes very rapidly, di/dt thus taking a negative value.

Upon turn on of the power electronic switches 18, voltages across the high frequency loop inductances, including the collector inductances 33 and the emitter inductances 30, are in the opposite direction.

It may be observed that a MOSFET leg, having a similar structure as the IGBT leg 70, may be built, in which case the power electronic switches 18 comprise a pair of MOSFETs replacing the IGBTs.

Referring back to FIG. 2, these voltages V_{LS} and V_{Le} are in series with V_{bus} from the voltage source 12. When the power electronic switch 18 turns off, the collector 22 to emitter 24 voltage increases until the freewheel diode 16 turns on. At that time, addition of V_{bus}, V_{Ls} and V_{Le} result in important overvoltage applied between the collector 22 and the emitter 24 of the power electronic switch 18. The same situation applies to both power electronic switches 18 (Q1 and Q2) of FIG. 5. Though power electronic switches are rated for operation at some level of voltage, extreme overvoltage can reduce the lifetime of any power electronic switch to thereby lead to its premature failure or even break the device.

Solutions exist that tend to limit overvoltage across power electronic switches by slowing down the slope of the gate-emitter voltage. However, excessive limitation of the overvoltage can imply longer switching times of the current, reducing commutation cell performance.

Therefore, there is a need for methods and circuits capable of reducing overvoltage occurring upon switching in commutation cells without causing undue switching delays.

### SUMMARY

According to the present disclosure, there is provided a gate driver for driving a power electronic switch of a commutation cell. The gate driver comprises a turn-off current source connected to a gate of the power electronic switch and an additional current source in parallel to the turn-off current source and configured to control a variation of a collector to emitter voltage of the power electronic switch at turn off of the power electronic switch.

According to another aspect of the present disclosure, there is also provided a circuit comprising a commutation cell. The commutation cell includes a power electronic switch having a collector, a gate and an emitter. Isolation between the collector and the gate forms a parasitic capacitance. The commutation cell further includes a freewheel diode, a capacitor and an inductance. A gate driver drives the power electronic switch. The gate driver includes a turn-off current source connected to the gate of the power electronic switch, and an additional current source in parallel to the turn-off current source. The additional current source is configured to control a collector to emitter voltage variation at turn off of the power electronic switch.

According to yet another aspect of the present disclosure, there is also provided a circuit comprising a leg having two commutation cells. Each commutation cell has a power electronic switch. Two gate drivers including turn-on and turn-off current sources are configured to turn on and then off one of the two power electronic switches while turning off and then on the other of the two power electronic switches. Two additional current sources are also included, each additional current source being in parallel with a turn-off current source of one of the two gate drivers.

A fourth aspect of the present disclosure relates to a converter configured to perform a conversion selected from a DC to DC conversion, a DC to AC conversion and an AC to DC conversion. The convertor includes one of the above described circuits, the circuit having at least one commutation cell having a power electronic switch, a gate driver including turn-on and turn-off current sources and an additional current source in parallel with the turn-off current source.

The foregoing and other features will become more apparent upon reading of the following non-restrictive description of illustrative embodiments thereof, given by way of example only with reference to the accompanying drawings.

### BRIEF DESCRIPTION OF THE DRAWINGS

Embodiments of the disclosure will be described by way of example only with reference to the accompanying drawings, in which:

FIG. 1 is an idealized circuit diagram of a conventional commutation cell having a single power electronic switch and a single freewheel diode with a voltage source and a current load;

FIG. 2 is another circuit diagram of the conventional commutation cell of FIG. 1, showing parasitic inductances and capacitances;

FIG. 3 is an illustration of an equivalent circuit of a typical IGBT;

FIG. 4 is a graph showing an example of switching losses of an IGBT as a function of gate resistance values;

FIG. 5 is a circuit diagram of a conventional IGBT leg having a pair of power electronic switches and further showing a gate driver;

FIG. 6 is a circuit diagram of a gate driver having an additional capacitor to control the voltage variation across the IGBT of a commutation cell according to an embodiment;

FIGS. 7a and 7b show two examples of current sources that may be used as a part of the gate driver of FIG. 6;

FIG. 8 is a graph illustrating the non-linearity of parasitic capacitances of an IGBT;

FIG. 9 is a graph showing a typical waveform of a high voltage IGBT at turn off using a gate driver having a single turn-off current source, without external capacitor; and

FIG. 10 is a graph showing a predicted waveform of the high voltage IGBT at turn off using the gate driver of FIG. 6, with an external capacitor.

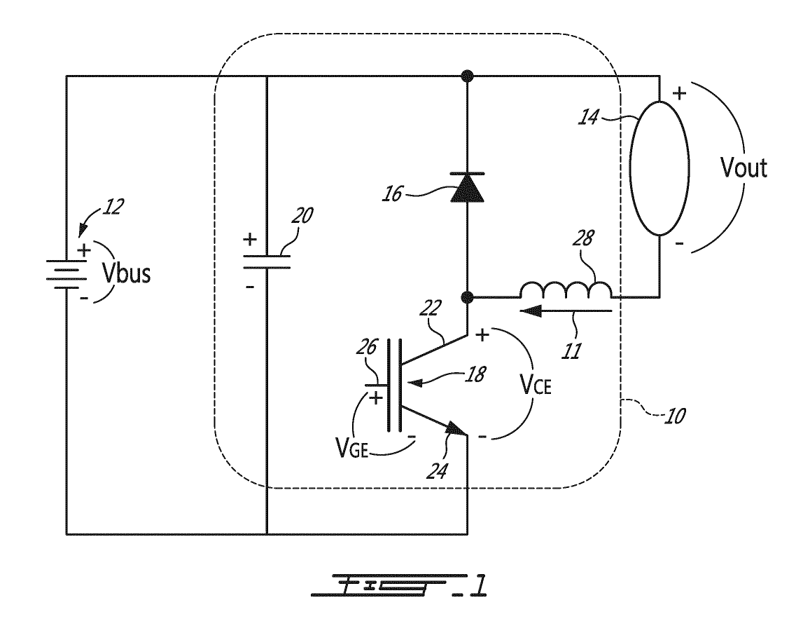

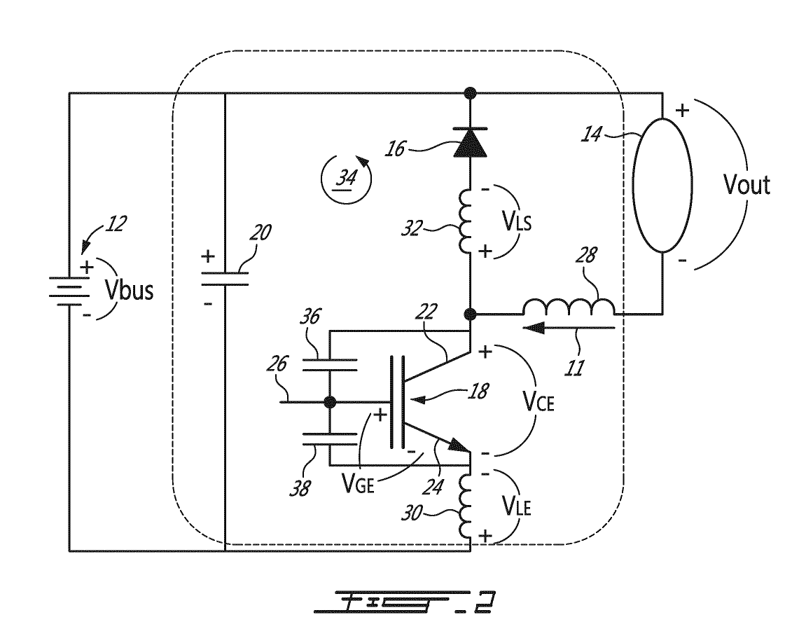

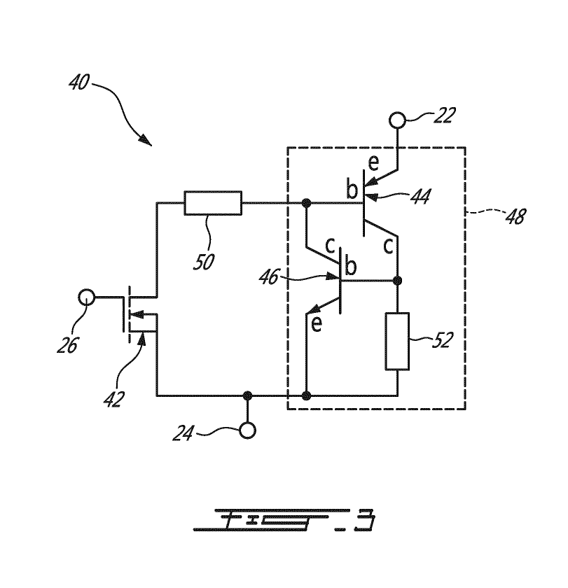

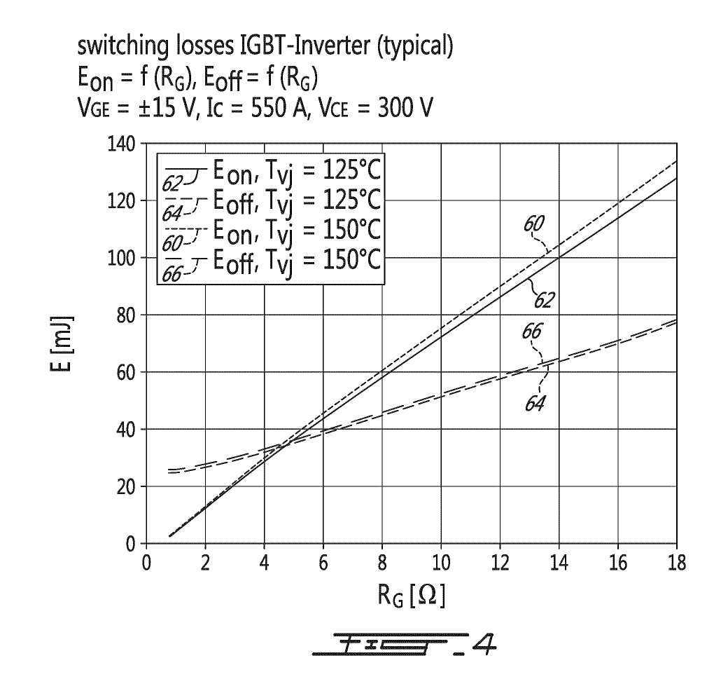

Like numerals represent like features on the various drawings.

### DETAILED DESCRIPTION

Various aspects of the present disclosure generally address one or more of the problems of overvoltage present in commutation cells at the time of switch off and the problems of excessive recovery current present in commutation cells at the time of switch on. Generally stated, the risk of failure of power electronic switches is expected to be reduced when overvoltage and excessive recovery current are under control. This may be achieved, at least in part, by maintaining the power electronic switches close to their linear region during the commutation process.

In one aspect, the present disclosure introduces a gate driver for driving a commutation cell comprising a power electronic switch. The power electronic switch has a collector, a gate and an emitter. Isolation between the collector and the gate forms a parasitic capacitance. The gate driver is configured as a pair of current sources connected to the gate of the power electronic switch, the current sources respectively providing a turn-on current and a turn-off current. An additional current source is placed in parallel to the turn-off current source of the gate driver and is configured to limit collector to emitter voltage variation (dV/dt) at turn off of the power electronic switch. Presence of the additional current source is instrumental in maintaining the power electronic switch into its linear operating region at turn-off.

In more details, in order to control the voltage variation across the collector and emitter of a power electronic switch such as an IGBT at turn off, the present technology slows down a variation of the gate voltage so that it remains slightly below the maximum rate of variation sustainable by the slowest sub-component of the whole power electronic switch.

Circuits operable to limit overvoltage in commutation cells, especially at turn off of IGBTs, are described in international patent applications PCT/CA2012/001125 and PCT/CA2013/000805, in U.S. provisional applications Nos. 61/808,254 and 61/904,038, and in “Reducing switching losses and increasing IGBT drive efficiency with Reflex™ gate driver technology”, available at http://www.advbe.com/docs/DeciElec2013-Jean_Marc_Cyr-TM4.pdf, all of which are authored by Jean-Marc Cyr et al., the disclosure of these being incorporated by reference herein. The present technology provides a reduction of overvoltage at turn off of a power electronic switch of a commutation cell. Solutions presented herein are generally compatible with other solutions to limit recovery current of the opposite diode and overvoltage across power electronic switches. As such, the solutions presented herein can be used alone or in combination with those described in international patent applications PCT/CA2012/001125 and PCT/CA2013/000805, in U.S. provisional applications Nos. 61/808,254 and 61/904,038, and in “Reducing switching losses and increasing IGBT drive efficiency with Reflex™ gate driver technology” to Jean-Marc Cyr et al.

FIG. 6 is a circuit diagram of a gate driver having an additional capacitor to control the voltage variation across the IGBT of a commutation cell according to an embodiment. Presence of the additional capacitor helps maintaining the IGBT in its linear region during the collector to emitter voltage variation (dV_{ce}/dt) period of the switching process. A commutation cell 100 comprises a power electronic switch 18. Other components of the communication cell 100, including a freewheel diode, a voltage source (e.g. an input capacitor) and a current load (e.g. an output inductance), are not shown in order to simplify the illustration; these elements have been introduced hereinabove. The power electronic switch 18 has a collector 22, a gate 26 and an emitter 24. Isolation between the collector 22 and the gate 26 forms a parasitic capacitance 36. A gate driver 72R shown on FIG. 6 comprises a turn-on current source 80 and a turn-off current source 82 connected to the gate 26 of the power electronic switch 18. The turn-on current source 80 provides a turn-on current Iₒₙ at turn on of the power electronic switch 18. The turn-off current source 82 provides a turn-off current I_{off} at turn off of the power electronic switch 18. An additional current source (described hereinbelow) is placed in parallel to the current sources 80, 82 of the gate driver 72R and is configured to limit collector to emitter voltage variation dV_{ce}/dt at turn off of the power electronic switch 18. Presence of the additional current source brings no significant effect at turn-on of the power electronic switch 18 because the dV_{ce}/dt is mainly driven by the recovery current of the freewheel diode and a parasitic capacitor of the freewheel diode (including the collector to emitter capacitor of the opposite power electronic switch in parallel with that freewheel diode) and the collector to emitter capacitor of the power electronic switch (including the freewheel diode capacitor in parallel therewith).

Presence within the gate driver 72R of the additional current source slows down a change, of a gate to emitter voltage V_{ge} and, consequently, of the collector to emitter voltage V_{ce}, at turn off of the power electronic switch 18. This helps maintaining the power electronic switch 18 in its linear region when the collector to emitter voltage V_{ce} increases. Without limitation, the additional current source may be constructed by connecting an external capacitor 102 in parallel with the parasitic capacitance 36, between the collector 22 and the gate 26. A value Cₑₓₜ of the external capacitor 102 may be determined using equation (2):

$${C}_{ext} = \frac{{I}_{off}}{{dV}_{cg} / dt} - {C}_{res} \qquad ( 2 )$$

wherein:
Cₑₓₜ is the value of the external capacitor 102;
I_{off} is a current provided by the gate driver 72R at turn off;
dV_{cg}/dt is a desired maximum variation of the collector to gate voltage V_{cg}; and
Cᵣₑₛ is a value of the parasitic capacitance 36 between the collector 22 and the gate 26.

As expressed hereinbelow, the value of Cᵣₑₛ varies as a function of a collector to emitter voltage of the IGBT. The value of the external capacitor Cₑₓₜ should be calculated, using equation (2), at high collector to emitter voltage, when Cᵣₑₛ is at its minimum.

FIG. 6 shows a ground reference 104. Voltages +V_{cc} and −V_{dd} of the gate driver 72R are defined in relation to the ground reference 104.

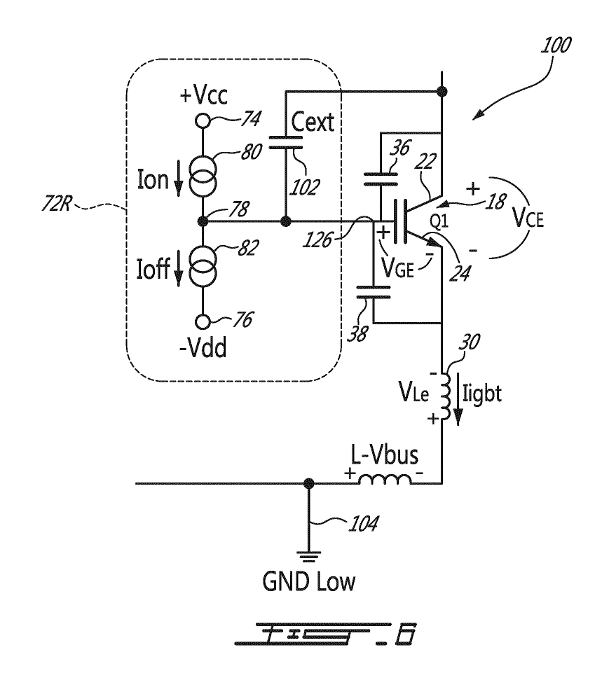

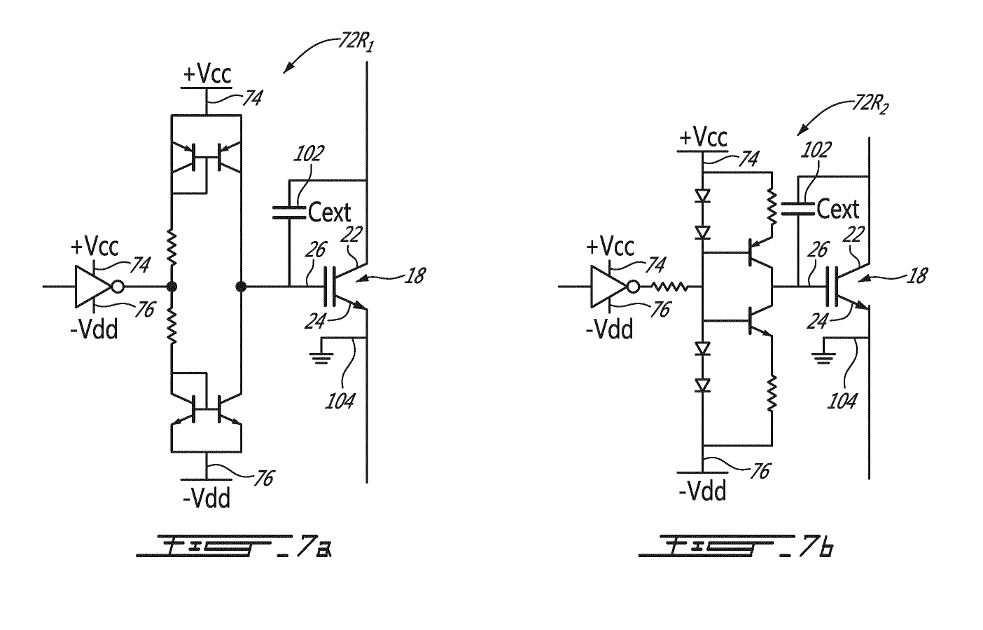

FIGS. 7a and 7b show two examples of current sources that may be used as a part of the gate driver of FIG. 6. Gate drivers 72R1 (FIG. 7a) and 72R2 (FIG. 7b) are variations of the gate driver 72R of FIG. 6. Gate drivers 72R1 and 72R2 both include the additional current source formed of the external capacitor 102 placed in parallel with the parasitic capacitance 36 (shown on other Figures) of the power electronic switches 18.

Another example of the current source may comprise a simple gate resistor having a value R_{G}. The performance of such a current source is affected by the variation of V_{ge(th)}, which changes with the current circulating in the power switch. The current source I_{off} provided by the gate resistor at turn off may be determined using equation (3):

$${I}_{off} = \frac{( - {V}_{dd} - {V}_{Le} ) - {V}_{ge ( th )}}{{R}_{G}} \qquad ( 3 )$$

wherein:
−V_{dd} is a voltage applied to the turn-off current source 82 of the gate driver 72R at turn off;
V_{Le} is a voltage on the emitter inductance 30;
V_{ge(th)} is a gate emitter threshold voltage of the power electronic switch 18; and
R_{G} is an output resistance value of the gate driver 72R, when the gate driver behaves as a current source.

While addition of the additional current source can be beneficial in controlling voltage variation at turn off of any commutation cell, it is particularly efficient in cases where the power electronic switch is a high voltage high power electronic none-linear switch, for example an isolated gate bipolar transistor.

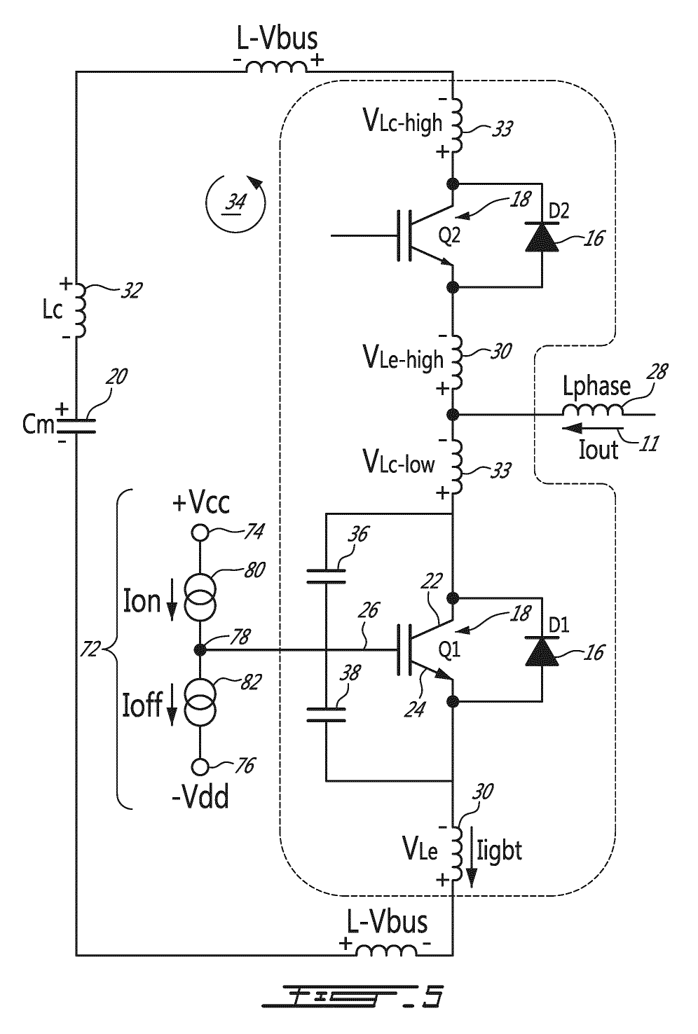

While FIG. 6 shows an additional current source 102 added to a gate driver of a commutation cell 100, inclusion of the additional current source is also applicable to the IGBT leg 70 of FIG. 5. In this case, one additional current source such as 102 is added in parallel to the existing current sources 80, 82 of each of the gate drivers 72. The additional current sources 102 may be matched or unmatched. Without limitation, the two additional current sources may comprise a pair of external capacitors 102 of substantially equal values, both of which are placed in parallel with collector to gate capacitances 36 of corresponding power electronic switches 18.

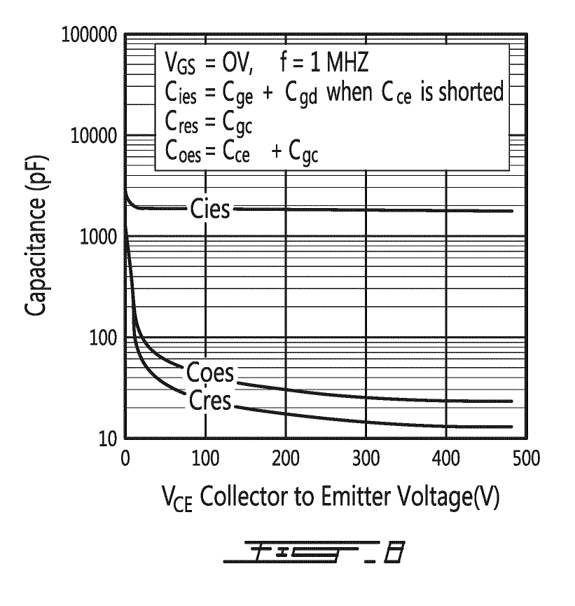

FIG. 8 is a graph illustrating the non-linearity of parasitic capacitances of an IGBT. The graph shows how values of the collector to gate parasitic capacitance 36 (Cᵣₑₛ), of the gate to emitter parasitic capacitance 38 (Cᵢₑₛ) and of a collector to emitter parasitic capacitance (Cₒₑₛ) vary as a function of the voltage V_{ce} between the collector 22 and the emitter 24. The parasitic capacitors of IGBTs are deeply nonlinear, as evidenced by the logarithmic vertical scale of the graph of FIG. 8. The capacitance values are fairly high when the voltage V_{ce} across the isolation barrier formed between the collector 22 and the emitter 24 is low. The capacitance values are much reduced when the voltage V_{ce} is high. For that reason, because the value Cᵣₑₛ of the parasitic capacitance 36 is small when the IGBT is subject to a high collector to emitter voltage V_{ce}, addition of the external capacitor 102 injecting in the gate 26 a current calculated as taught in the present disclosure allows maintaining the IGBT in its linear region without inducing significant effect at low values of the collector to emitter voltage V_{ce}.

A variation of the current flowing into the collector and emitter of the IGBT induces the voltage V_{Le} across the emitter inductance 30. During dV_{ce}/dt, current circulates in an output capacitor Cₒₑₛ of the IGBT. Because the added current source limits the dV_{ce}/dt to a fixed predetermined value, virtually no voltage is induced across the emitter inductance 30 (Le). Though V_{Le} is added to the power supply voltage source with the polarity indicated on FIG. 6, this value is near zero. If a gate resistor is used as a current source, considering equation (3), it can be observed that V_{Le} limits the voltage of the current I_{off} provided by the gate driver 72R at turn off. Current circulating in the collector to gate parasitic capacitance 36 (known as a ‘Miller Current’) and in the external capacitor 102 is maintained to a low value, reducing switching losses caused by the addition of the external capacitor 102. In some practical realizations, it has been found that an optimal value of the external capacitor 102 was in the order of magnitude of the smallest value of the collector to gate parasitic capacitance 36, in which case impact of the addition of the external capacitor 102 to energy dissipation in the gate driver 72R was not significant.

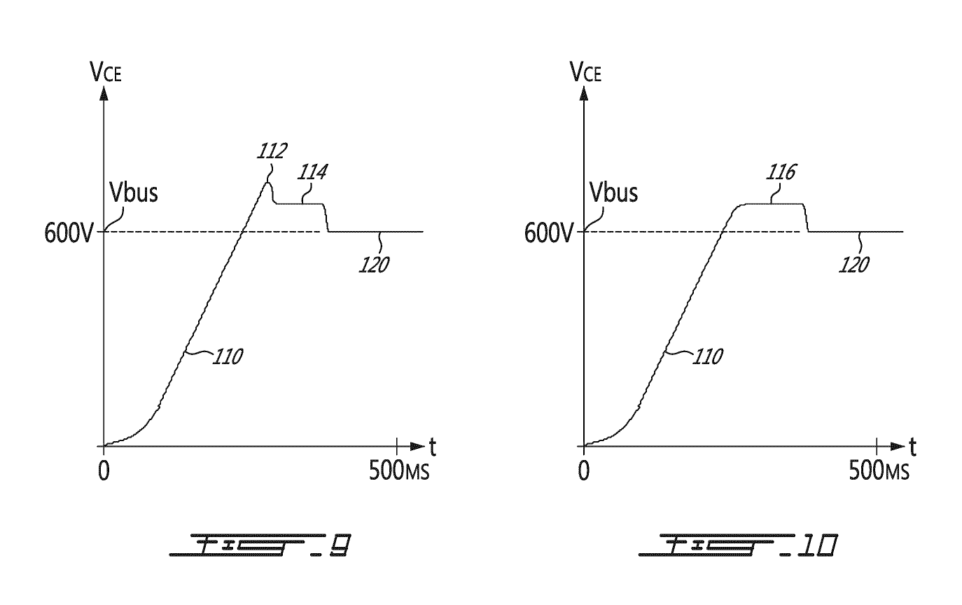

FIG. 9 is a graph showing a typical waveform of a high voltage IGBT at turn off using a gate driver having a single turn-off current source, without external capacitor. FIG. 10 is a graph showing a predicted waveform of the high voltage IGBT at turn off using the gate driver of FIG. 6, with an external capacitor. Both figures use the emitter inductance 30 to limit the overvoltage. The gate driver of FIG. 6 includes the additional current source induced by the dV_{ce}/dt across the external capacitor 102. FIGS. 9 and 10 use equivalent scales on their vertical (voltage) and horizontal (time) axes. Comparing the graphs of FIGS. 9 and 10, both graphs show a rapid increase 110 of the collector to emitter voltage V_{ce} upon turn off of the IGBT. Both graphs show that the V_{ce} eventually reaches a plateau 114 or 116 and then a steady level 120 equal to the DC voltage V_{bus} when the switching process is complete. However, without the additional current source of FIG. 6, FIG. 9 shows a high overvoltage peak 112 of the V_{ce} occurring at the end of the rapid increase 110, before the plateau 114 that leads to the steady level 120. In the case of FIG. 9, it may be observed that the equivalent input MOSFET of the IGBT goes out of its linear region during the collector to emitter voltage rise, at turn off. The high overvoltage peak 112 between the collector and the emitter V_{ce} is caused by a delay of the gate to emitter voltage V_{ge} before returning into its linear region. In contrast, as shown on FIG. 10, the high overvoltage peak 112 is eliminated and replaced by a lower plateau 116 leading to the steady level 120. The IGBT stays in its linear region during the entire switching process at turn off. The difference is due to the presence of the additional current source of FIG. 6 built with the external capacitor 102 generating a current during the dV/dt that helps eliminating the delay on the gate to emitter voltage V_{ge}, maintaining the gate to emitter voltage V_{ge} in its linear region. Without limiting the present disclosure, the examples of FIGS. 9 and 10 show a bus voltage V_{bus} of about 600 volts, the rapid increase 110 of the collector to emitter voltage V_{ce} having a duration of about 100 to 150 μsec.

The foregoing provides a description of a solution applicable to commutation cells that may be used in any configurations, including a full leg of semiconductors in DC-DC converters as well as to DC-AC converters or AC-DC converters, to provide, for example, alternative current to a connected load such as a motor of an electric vehicle.

Those of ordinary skill in the art will realize that the description of the gate driver and circuits are illustrative only and are not intended to be in any way limiting. Other embodiments will readily suggest themselves to such persons with ordinary skill in the art having the benefit of the present disclosure. Furthermore, the disclosed gate driver and circuits may be customized to offer valuable solutions to existing needs and problems of overvoltage occurring upon switching in commutation cells.

In the interest of clarity, not all of the routine features of the implementations of the gate driver and circuits are shown and described. It will, of course, be appreciated that in the development of any such actual implementation of the gate driver and circuits, numerous implementation-specific decisions may need to be made in order to achieve the developer's specific goals, such as compliance with application-, system-, and business-related constraints, and that these specific goals will vary from one implementation to another and from one developer to another. Moreover, it will be appreciated that a development effort might be complex and time-consuming, but would nevertheless be a routine undertaking of engineering for those of ordinary skill in the field of power electronics having the benefit of the present disclosure.

It is to be understood that the gate driver and circuits are not limited in its application to the details of construction and parts illustrated in the accompanying drawings and described hereinabove.

The proposed gate driver and circuits are capable of other embodiments and of being practiced in various ways. It is also to be understood that the phraseology or terminology used herein is for the purpose of description and not limitation. Hence, although the, gate driver and circuits have been described hereinabove by way of illustrative embodiments thereof, the scope of the claims should not be limited by the embodiments set forth in the examples, but should be given the broadest interpretation consistent with the description as a whole.

1. A gate driver for driving a power electronic switch of a commutation cell, comprising:
a turn-off current source connected to a gate of the power electronic switch; and
an additional current source in parallel to the turn-off current source and configured to control a variation of a collector to emitter voltage of the power electronic switch at turn off of the power electronic switch.

2. The gate driver of claim 1, wherein the additional current source is configured to limit a rate of variation of a voltage at the gate of the power electronic switch.

3. The gate driver of claim 1, wherein the additional current source is configured to maintain a gate to emitter voltage of the power electronic switch in a linear region at turn off of the power electronic switch.

4. The gate driver of claim 1, wherein the additional current source comprises an external capacitor connected between the collector and the gate of the power electronic switch.

5. The gate driver of claim 4, wherein the external capacitor is connected in parallel to a parasitic capacitance between the collector and the gate of the power electronic switch.

6. The gate driver of claim 5, wherein a value of the external capacitor is determined using:
$${C}_{ext} = \frac{{I}_{off}}{{dV}_{cg} / dt} - {C}_{res}$$
wherein:
Cₑₓₜ is the value of the external capacitor;
I_{off} is a current provided by the turn-off current source of the gate driver at turn off;
dV_{cg}/dt is a desired maximum variation of the collector to gate voltage V_{cg}; and
Cᵣₑₛ is a value of the parasitic capacitance between the collector and the gate.

7. The gate driver of claim 5, wherein a value of the external capacitor is in an order of magnitude of a minimum value of the parasitic capacitance between the collector and the gate of the power electronic switch.

8. The gate driver of claim 1, wherein the power electronic switch is selected from an isolated gate bipolar transistor, a bipolar transistor and a metal-oxide-semiconductor field-effect transistor.

9. A circuit, comprising:
a commutation cell including a power electronic switch having a collector, a gate and an emitter, isolation between the collector and the gate forming a parasitic capacitance, the commutation cell further including a freewheel diode, a capacitor and an inductance; and
a gate driver for driving the power electronic switch, the gate driver including a turn-off current source connected to the gate of the power electronic switch, the gate driver further including an additional current source in parallel to the turn-off current source and configured to control a collector to emitter voltage variation at turn off of the power electronic switch.

10. The circuit of claim 9, wherein the additional current source is configured to limit a rate of variation of a voltage across the collector to emitter of the power electronic switch.

11. The circuit of claim 9, wherein the additional current source is configured to maintain a gate to emitter voltage of the power electronic switch in a linear region at turn off of the power electronic switch.

12. The circuit of claim 9, wherein the additional current source comprises an external capacitor connected between the collector and the gate of the power electronic switch.

13. The circuit of claim 12, wherein the external capacitor is connected in parallel to the parasitic capacitance between the collector and the gate of the power electronic switch.

14. The circuit of claim 13, wherein a value of the external capacitor is determined using:
$${C}_{ext} = \frac{{I}_{off}}{{dV}_{cg} / dt} - {C}_{res}$$
wherein:
Cₑₓₜ is the value of the external capacitor;
I_{off} is a current provided by the turn-off current source of the gate driver at turn off;
dV_{cg}/dt is a desired maximum variation of the collector to gate V_{cg} voltage; and
Cᵣₑₛ is a value of the parasitic capacitance between the collector and the gate.

15. The circuit of claim 13, wherein a value of the external capacitor is in an order of magnitude of a minimum value of the parasitic capacitance between the collector and the gate of the power electronic switch.

16. The circuit of claim 9, wherein the power electronic switch is selected from an isolated gate bipolar transistor, a bipolar transistor and a metal-oxide-semiconductor field-effect transistor.

17. A circuit, comprising:
a leg having two commutation cells, each commutation cell having a power electronic switch;
two gate drivers including turn-on and turn-off current sources configured to turn on and then off one of the two power electronic switches while turning off and then on an other one of the two power electronic switches; and
two additional current sources, each additional current source being in parallel with a turn-off current source of one of the two gate drivers.

18. The circuit of claim 17, wherein the two additional current sources comprises two external capacitors having substantially equal capacitance values.

19. The circuit of claim 17, wherein the two additional current sources comprise two matched current sources.

20. The circuit of claim 17, wherein the two additional current sources comprise two unmatched current sources.

21. A converter, comprising:
a circuit of claim 9;
wherein the converter is configured to perform a conversion selected from a DC to DC conversion, a DC to AC conversion and an AC to DC conversion.
